(19) United States
(12) Patent Application Publication
(10) Pub. No.: US 2013/0271229 A1
(43) Pub. Date: Oct. 17, 2013

(54) METHOD AND APPARATUS FOR LOCAL OSCILLATOR

(71) Applicant: MARVELL WORLD TRADE LTD, St. Michael (BB)

(72) Inventors: Xiang GAO, San Jose, CA (US); Chi-Hung Lin, Fremont, CA (US); Li Lin, Saratoga, CA (US)

(73) Assignee: Marvell World Trade Ltd., St. Michael (BB)

(21) Appl. No.: 13/861,125

(22) Filed: Apr. 11, 2013

Related U.S. Application Data
(60) Provisional application No. 61/623,188, filed on Apr. 12, 2012.

(51) Int. Cl. H03L 7/06

(52) U.S. Cl. CPC H03L 7/06
USPC 331/19

(57) ABSTRACT

Aspects of the disclosure provide a local oscillator (LO) circuit that includes a first phase locked loop (PLL) circuit and a second PLL. The first PLL circuit is configured to generate a first oscillation signal having a first frequency based on a reference signal having a reference frequency. The second PLL circuit is configured to receive the first oscillation signal and generate a second oscillation signal having a second frequency based on the first oscillation signal.

### INCORPORATION BY REFERENCE

This present disclosure claims the benefit of U.S. Provisional Application No. 61/623,188, “Flexible Local Oscillator Generation Scheme for Wireless Transceivers” filed on Apr. 12, 2012, which is incorporated herein by reference in its entirety.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Many circuits, such as wireless transceivers, data converters, wireline and optical serial data communication links, processors, and the like, operate based on a periodic signal. Generally, the periodic signal can be generated by a local oscillator circuit. In an example, a local oscillator circuit includes a phase locked loop (PLL) circuit to generate an oscillation signal having a relatively high frequency based on a reference oscillation signal. The reference oscillation signal can be generated by a crystal oscillator, and can have a relatively low frequency.

### SUMMARY

Aspects of the disclosure provide a local oscillator (LO) circuit that includes a first phase locked loop (PLL) circuit and a second PLL circuit. The first PLL circuit is configured to generate a first oscillation signal having a first frequency based on a reference signal having a reference frequency. The second PLL circuit is configured to receive the first oscillation signal and generate a second oscillation signal having a second frequency based on the first oscillation signal. In an example, the reference signal is a reference oscillation signal.

In an embodiment, a periodic signal used in a power amplifier is generated based on the second oscillation signal, and a frequency difference between the first oscillation signal and the periodic signal is larger than a threshold. In an example, the first PLL circuit is configured to have a first bandwidth that is smaller than a modulation frequency in the power amplifier and the second PLL circuit is configured to have a second bandwidth that is larger than the modulation frequency in the power amplifier.

In an embodiment, the first PLL circuit includes a first divider, a first error detecting and controlling circuit and a first voltage controlled oscillator. The first divider is configured to frequency-divide the first oscillation signal to generate a first feedback signal. The first error detecting and controlling circuit is configured to detect a first phase/frequency error between the first feedback signal and the reference signal and generate a first control voltage based on the first phase/frequency error. The first voltage controlled oscillator is configured to adjust the first frequency based on the first control voltage.

Further, in an embodiment, the second PLL circuit includes a second divider, a third divider, a second error detecting and controlling circuit, and a second voltage controlled oscillator. The second divider is configured to frequency-divide the first oscillation signal. The third divider is configured to frequency-divide the second oscillation signal to generate a second feedback signal. The second error detecting and controlling circuit is configured to detect a second phase/frequency error between the second feedback signal and the frequency-divided first oscillation signal and generate a second control voltage based on the second phase/frequency error. The second voltage controlled oscillator is configured to adjust the second frequency based on the second control voltage.

In an embodiment, the LO circuit includes a fourth divider configured to frequency-divide the second oscillation signal.

According to an aspect of the disclosure, the LO circuit includes a controller configured to control at least one of the first divider, the second divider and the third divider to adjust the second frequency.

Aspects of the disclosure provide a method. The method includes receiving a reference signal having a reference frequency, generating, by a first phase-locked loop (PLL) circuit, a first oscillation signal having a first frequency with phase locked to the reference signal, and generating, by a second PLL circuit, a second oscillation signal having a second frequency with phase locked to the first oscillation signal.

Aspects of the disclosure provide an integrated circuit (IC) chip that includes a first PLL circuit, a second PLL circuit, and a power amplifier. The first phase locked loop (PLL) circuit is configured to generate a first oscillation signal having a first frequency based on a reference signal having a reference frequency. The second PLL circuit is configured to receive the first oscillation signal and generate a second oscillation signal having a second frequency based on the first oscillation signal. The power amplifier is configured to operate based on a periodic signal generated based on the second oscillation signal, and a frequency difference between the first oscillation signal and the periodic signal is larger than a threshold.

### BRIEF DESCRIPTION OF THE DRAWINGS

Various embodiments of this disclosure that are proposed as examples will be described in detail with reference to the following figures, wherein like numerals reference like elements, and wherein:

FIG. 1 shows a block diagram of an integrated circuit (IC) chip example 100 according to an embodiment of the disclosure;

FIG. 2 shows a table for generating a local oscillator signal according to an embodiment of the disclosure; and

FIG. 3 shows a flow chart outlining a process example 300 according to an embodiment of the disclosure.

### DETAILED DESCRIPTION OF EMBODIMENTS

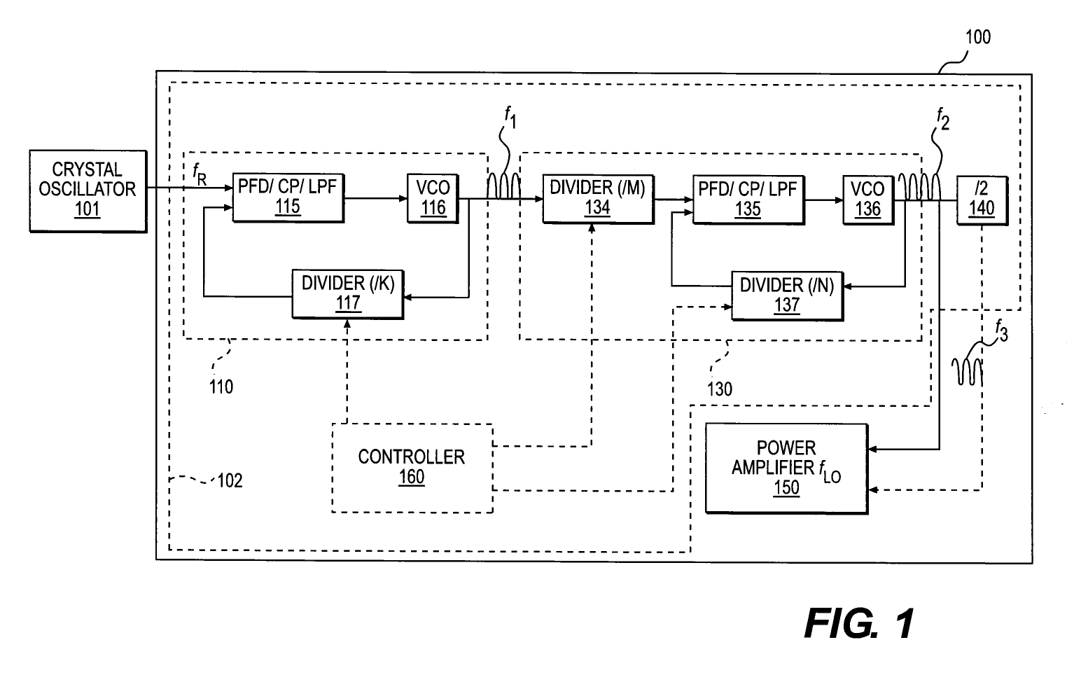

FIG. 1 shows a block diagram of an integrated circuit (IC) chip example 100 according to an embodiment of the disclosure. The IC chip 100 includes a local oscillator (LO) circuit 102 configured to generate a periodic signal for other circuits on the IC chip 100, such as a power amplifier (PA) 150, and the like. The LO circuit 102 includes a first phase-locked loop (PLL) circuit 110 and a second PLL circuit 130. The first PLL circuit 110 is configured to generate a first oscillation signal having a first frequency (f₁) based on a reference signal, such as a reference oscillation signal, having a reference frequency (f_{R}). The second PLL circuit is configured to receive the first oscillation signal and generate a second oscillation signal having a second frequency (f₂) based on the first oscillation signal. These elements are coupled together as shown in FIG. 1. It is noted that, in another embodiment, the elements on the IC chip 100 can be implemented on multiple IC chips and the elements can be coupled together across the multiple IC chips.

Specifically, in the FIG. 1 example, the first PLL circuit 110 includes a first error detecting and controlling circuit 115, a first voltage controlled oscillator (VCO) 116 and a first divider 117. The second PLL circuit 130 includes a second divider 134, a second error detecting and controlling circuit 135, a second voltage controlled oscillator (VCO) 136 and a third divider 137. These elements are coupled together as shown in FIG. 1.

In an example, the first error detecting and controlling circuit 115 receives the reference oscillation signal and a first feedback signal generated by the first divider 117. The first divider 117 generates the first feedback signal by frequency-dividing the first oscillation signal. Thus, the frequency and the phase of the first feedback signal are related to the frequency and the phase of the first oscillation signal. The first error detecting and controlling circuit 115 detects a first frequency or phase error between the reference oscillation signal and the first feedback signal, and generates a first control voltage based on the first error. It is noted that the first error detecting and controlling circuit 115 can be implemented by various techniques. In the FIG. 1 example, the first error detecting and controlling circuit 115 is implemented by a combination of phase/frequency detector (PFD), charge pump (CP), and low pass filter (LPF).

The first control voltage is provided to the first VCO 116 to adjust the first frequency f₁ in a manner to reduce the first error and lock the first PLL 110. When the first PLL 110 is suitably locked, the first frequency f₁ is a multiplication of the reference frequency f_{R}. In an example, the divider 117 divides the first frequency by K, and thus the first frequency f₁=K×f_{R}.

It is noted that K can be an integer and can be a fractional number, such as an improper fraction, and the like. In an example, K can be adjusted, such that the first frequency f₁ varies based on the value of K, for example.

In an embodiment, the first VCO 116 includes an LC tank circuit. The inductance and/or capacitance of the LC tank circuit can be controlled based on the first control voltage to adjust the first frequency f₁ of the first oscillation signal. In another embodiment, the first VCO 116 includes a ring oscillator having a plurality of delay stages coupled together in a ring. The delay of the delay stages can be controlled based on the first control voltage to adjust the first frequency f₁ of the first oscillation signal. In an example, the first VCO 116 has a tuning range, and the quality of the first oscillation signal, such as a signal to noise ratio, is related to the tuning range. For example, when the tuning range is small, the first oscillation signal has a relatively high signal to noise ratio.

Further, the second divider 134 frequency-divides the first oscillation signal by M to generate a frequency-divided first oscillation signal. The second error detecting and controlling circuit 135 receives the frequency-divided first oscillation signal and a second feedback signal generated by the third divider 137. The third divider 137 generates the second feedback signal by frequency-dividing the second oscillation signal. Thus, the frequency and the phase of the second feedback signal are related to the frequency and the phase of the second oscillation signal. The second error detecting and controlling circuit 135 detects a second frequency or phase error between the frequency-divided first oscillation signal and the second feedback signal, and generates a second control voltage based on the second error. It is noted that the second error detecting and controlling circuit 135 can be implemented by various techniques. In the FIG. 1 example, the second error detecting and controlling circuit 135 is implemented by a combination of phase/frequency detector (PFD), charge pump (CP), and low pass filter (LPF).

The second control voltage is provided to the second VCO 136 to adjust the second frequency f₂ in a manner to reduce the second error and lock the second PLL circuit 130. When the second PLL circuit 130 is suitably locked, the second frequency f₂ is a function of the first frequency f₁. In an example, the second divider 134 frequency-divides the first frequency f₁ by M, the third divider 137 frequency-divides the second frequency f₂ by N, and thus the second frequency f₂=N/M×f₁.

It is noted that M and N can be integers and can be fractional numbers. In an example, M and N can be adjusted.

In an embodiment, the second VCO 136 includes an LC tank circuit. The inductance and/or capacitance of the LC tank circuit can be controlled based on the second control voltage to adjust the second frequency f₂ of the second oscillation signal. In another embodiment, the second VCO 136 includes a ring oscillator having a plurality of delay stages coupled together in a ring. The delay of the delay stages can be controlled based on the second control voltage to adjust the second frequency f₂ of the second oscillation signal.

It is also noted that the LO circuit 102 can include other suitable circuits. In the FIG. 1 example, the LO circuit 102 includes a fourth divider 140 configured to frequency-divide the second oscillation signal. For example, the fourth divider 140 can frequency-divide the second oscillation signal by two and output a frequency-divided second oscillation signal. The LO circuit 102 can provide the second oscillation signal or the frequency-divided second oscillation signal as the local oscillation signal (LO) having a local oscillation frequency (f_{LO}) to the other circuits, such as the PA 150, on the IC chip 100.

Further, in the FIG. 1 example, the LO circuit 102 includes a controller 160. The controller 160 provides control signals to the first divider 117, the second divider 134 and the third divider 137 to adjust K, M and N in an example.

According to an aspect of the disclosure, the reference oscillation signal may be provided from a source that is off the IC chip 100, such as an external crystal oscillator 101 in an example. It is noted that, in another example, a reference signal can be provided from a source that is on the IC chip 100. The first PLL circuit 110 is configured to have a relatively small bandwidth to reject a large portion of jitter that may come into the IC chip 100 with the reference oscillation signal. In an example, the reference frequency f_{R} is in the order of 40 MHz, the first PLL circuit 110 is configured to have a bandwidth about one tenth of the reference frequency f_{R}, such as about 4 MHz, to reject jitter that comes in the IC chip 100 with the reference oscillation signal, and is out of the bandwidth.

Further, because of the small bandwidth, the first PLL 110 does not attenuate fast jitter introduced by the first VCO 116. In an embodiment, the first PLL 110 is suitably configured such that the first frequency f₁ is significantly different from the operation frequency, such as the local frequency (f_{LO}) of the PA 150 to avoid PA pulling. For example, the difference between the first frequency f₁ and the local frequency f_{LO} is larger than a threshold.

Generally, the PA 150 uses the local oscillation signal as a carrier signal. The carrier signal is modulated according to a modulation frequency (f_{D}) corresponding to a data rate to carry information. In an example, the modulation frequency f_{D} is about 10 MHz.

When the first frequency f₁ is equal or close to f_{LO}, because the PA 150 has a large output power, a portion of the power may be coupled to the first VCO 116, for example the LC tank circuit of the first VCO 116. Thus, the first frequency f₁ of the first oscillation signal may be pulled away to the PA frequency that is modulated according to the modulation frequency. Because the bandwidth of the first PLL 110, for example about 4 MHz, is smaller than the modulation frequency, about 10 MHz, the first detecting and controlling circuit 115 heavily attenuates the portion having the modulation frequency in the first error, and thus jitter in the first VCO 116 due to the modulation frequency cannot be corrected.

In the embodiment, when the first PLL 110 is suitably configured such that the first frequency f₁ is significantly different from the local oscillation frequency f_{LO} of the PA 150, the portion of the power coupled to the LC tank circuit does not affect the operation of the first VCO 116.

Further, according to an aspect of the disclosure, the second PLL 110 is configured to have a relatively large bandwidth to reject PA pulling. In an example, the first frequency f₁ is in the order of a few GHz, and the second PLL 110 is configured to have a bandwidth about one tenth of the first frequency f₁, for example a few hundreds of MHz.

During operation, a portion of the PA 150 power may be coupled to the second VCO 136. Assuming, at a time, the second frequency f₂ of the second oscillation signal is pulled away to the PA frequency that is modulated according to the modulation frequency. Because the bandwidth of the second PLL 130, for example a few hundreds of MHz, is larger than the modulation frequency, about 10 MHz, the second detecting and controlling circuit 135 passes the portion having the modulation frequency in the second error to generate the second control voltage, and thus jitter in the second VCO 136 due to the PA pulling can be corrected.

According to an aspect of the disclosure, the LO circuit 102 saves signal power compared to a related implementation. In the related implementation, a mixer is used in the place of the second PLL 130. The mixer generates two frequency components, and then uses a LC tank circuit centered at one frequency to select the frequency component and reject the other frequency component. Thus, half of the signal power is wasted.

Further, the LO circuit 102 achieves a lower spur level compared to the related implementation. For example, the related implementation relies on the LC tank circuit to reduce the spur level. In an example, an on-chip LC tank circuit can have a quality factor (Q) in the order of 10, and the spur level is typically larger than −30 dBc. The spur level of the LO circuit 102 is independent of the LC tank circuit, and depends on the design of the second PLL 130. In an example, the second PLL 130 can easily achieve −60 dBc, and even −80 dBc.

In an embodiment, because the spur level of the LO circuit 102 does not rely on the LC tank circuit, the second VCO 136 is implemented using a ring oscillator that occupies a smaller silicon area than an LC tank circuit.

Further, according to an aspect of the disclosure, the LO circuit 102 has improved flexibility for tuning. In an embodiment, the controller 160 controls K, N and M to avoid generating spur at certain frequency for multi-radio co-existence. In an example, the IC chip 100 includes another power amplifier (not shown) that operates in a different radio frequency band. The controller 160 determines suitable values for K, M and N to avoid interferences with co-existence ratios, and adjusts K, N and M accordingly.

In another embodiment, the controller 160 controls K, N and M to choose a sub-band. In an example, the first VCO 116 has a tuning range. The controller 160 controls K to cause the second frequency f₂ to be a desired frequency for a sub-band. In another example, the first VCO 116 can be configured to have a reduced tuning range to improve performance. The controller 160 controls K, M and N to cause the second frequency f₂ to be the desired frequency for the sub-band. In another example, K is fixed, and the controller 160 controls M and N to cause the second frequency f₂ to be the desired frequency for the sub-band.

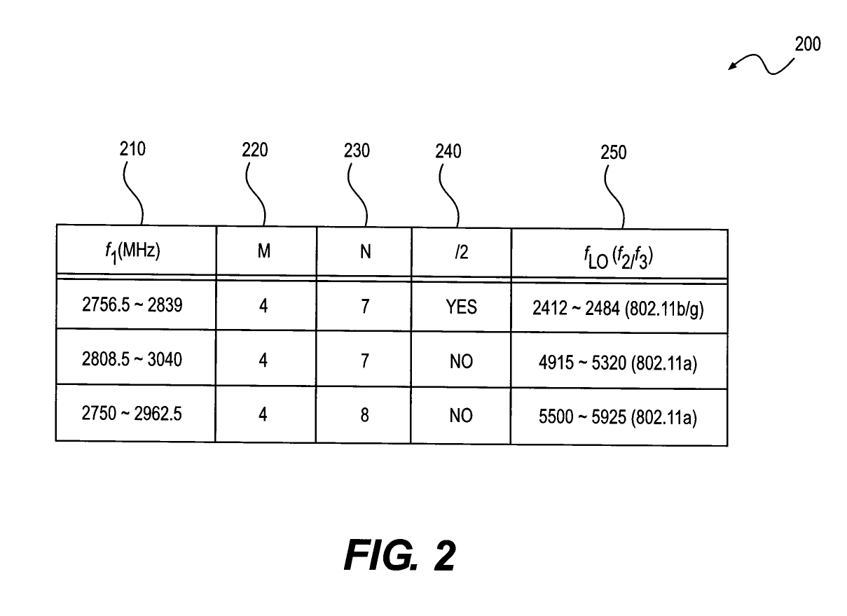

FIG. 2 shows a table 200 for configuring the LO circuit 102 to generate the local oscillator signal according to an embodiment of the disclosure. The table 200 includes a first column 210 showing a range of the first frequency f₁, a second column 220 for M, a third column 230 for N, a fourth column 240 for indicating whether the divider 140 is used, and a fifth column 250 showing the range of the local oscillator frequency f_{LO}.

In the FIG. 2 example, by suitably tuning the first frequency f₁, selecting values for M and N, and configuring the divider 140 (e.g., first row and second row in the table 200), the LO circuit 102 can generate the local oscillation signal for different wireless communication protocols, such as 802.11b/g, 802.11a, and the like. Further, by suitably tuning the first frequency f₁, selecting values for M and N (e.g., second row and third row in the table 200), the LO circuit 102 can generate the local oscillation signal in different sub-bands to avoid interference with co-existence radios, for example.

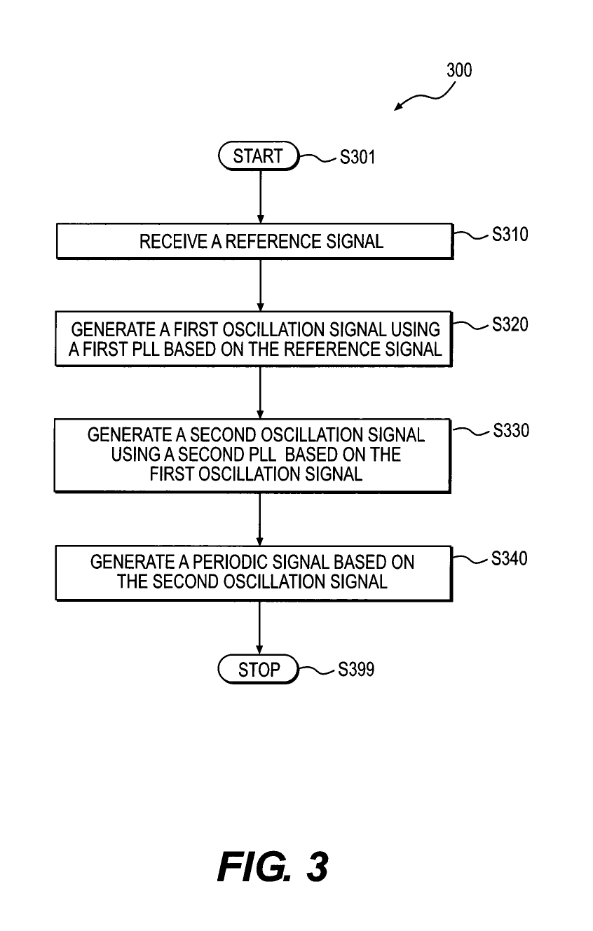

FIG. 3 shows a flow chart outlining a process example executed in an LO circuit, such as the LO circuit 102, according to an embodiment of the disclosure. The LO circuit generates a periodic signal (local oscillator signal) for use in a power amplifier. The process starts at S301, and proceeds to S310.

At S310, a reference signal is received. In an example, the reference signal is a reference oscillation signal. In the FIG. 1 example, the crystal oscillator 101 that is off the IC chip 100 generates the reference oscillation signal. The reference oscillation signal is then provided to the LO circuit 102 via various conductive components, such as metal wires, traces, vias, and the like. It is noted that jitter may come into the IC chip 100 with the reference oscillation signal.

At S320, a first oscillation signal is generated by a first PLL circuit based on the reference signal. In the FIG. 1 example, the first PLL circuit 110 receives the reference oscillation signal and generates the first oscillation signal based on the reference oscillation signal. In an example, the first PLL circuit 110 has a relatively small bandwidth to reject a large portion of jitter coming into the IC chip 100 with the reference oscillation signal. In addition, in an example, a frequency difference between the first oscillation signal and the local oscillator signal is larger than a threshold, such that the operation of the first VCO 116 is not affected by the PA 150.

At S330, a second oscillation signal is generated by a second PLL circuit based on the first oscillation signal. In the FIG. 1 example, the second PLL circuit 130 receives the first oscillation signal and generates the second oscillation signal based on the first oscillation signal. In an example, the second PLL circuit 130 has a relatively large bandwidth, such as larger than the modulation frequency in the PA 150. Then, the PA pulling induced jitter can be rejected in the second PLL circuit 130.

At S340, the periodic signal for use in the power amplifier is generated based on the second oscillation signal. In an example, the second oscillation signal is provided to the power amplifier. In another example, the second oscillation signal is further processed, such as frequency-divided, to generate the second oscillation signal. Then, the process proceeds to S399 and terminates.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A local oscillator (LO) circuit, comprising:
a first phase locked loop (PLL) circuit configured to generate a first oscillation signal having a first frequency based on a reference signal having a reference frequency; and
a second PLL circuit configured to receive the first oscillation signal and generate a second oscillation signal having a second frequency based on the first oscillation signal.

2. The LO circuit of claim 1, wherein a periodic signal used in a power amplifier is generated based on the second oscillation signal, and a frequency difference between the first oscillation signal and the periodic signal is larger than a threshold.

3. The LO circuit of claim 2, wherein the first PLL circuit is configured to have a first bandwidth that is smaller than a modulation frequency in the power amplifier and the second PLL circuit is configured to have a second bandwidth that is larger than the modulation frequency in the power amplifier.

4. The LO circuit of claim 1, wherein the first PLL circuit comprises:
a divider configured to frequency-divide the first oscillation signal to generate a feedback signal;
an error detecting and controlling circuit configured to detect an error between the feedback signal and the reference signal and generate a control voltage based on the error; and
a voltage controlled oscillator configured to adjust the first frequency based on the control voltage.

5. The LO circuit of claim 4, wherein the divider is a first divider, the feedback signal is a first feedback signal, the error detecting and controlling circuit is a first error detecting and controlling circuit, the error is a first error, the control voltage is a first control voltage, the voltage controlled oscillator is a first voltage controlled oscillator, and the second PLL circuit comprises:
a second divider configured to frequency-divide the first oscillation signal;
a third divider configured to frequency-divide the second oscillation signal to generate a second feedback signal;
a second error detecting and controlling circuit configured to detect a second error between the second feedback signal and the frequency-divided first oscillation signal and generate a second control voltage based on the second error; and
a second voltage controlled oscillator configured to adjust the second frequency based on the second control voltage.

6. The LO circuit of claim 5, further comprising:
a fourth divider configured to frequency-divide the second oscillation signal.

7. The LO circuit of claim 5, further comprising:
a controller configured to control at least one of the first divider, the second divider and the third divider to adjust the second frequency.

8. The LO circuit of claim 1, wherein the reference signal is a reference oscillation signal.

9. A method, comprising:
receiving a reference signal having a reference frequency;
generating, by a first phase-locked loop (PLL) circuit, a first oscillation signal having a first frequency with phase locked to the reference signal; and
generating, by a second PLL circuit, a second oscillation signal having a second frequency with phase locked to the first oscillation signal.

10. The method of claim 9, further comprising:
generating a periodic signal for use in a power amplifier based on the second oscillation signal, a frequency difference between the first oscillation signal and the periodic signal being larger than a threshold.

11. The method of claim 10, wherein generating the first oscillation signal by the first PLL circuit having a first band width that is smaller than a modulation frequency in the power amplifier;
generating the second oscillation signal by the second PLL circuit having a second bandwidth that is larger than the modulation frequency in the power amplifier.

12. The method of claim 9, wherein generating, by the first PLL circuit, the first oscillation signal having the first frequency with phase locked to the reference signal comprises:
frequency-dividing the first oscillation signal to generate a feedback signal;
detecting an error between the first feedback signal and the reference signal;
generating a control voltage based on the error; and
controlling a voltage controlled oscillator that generates the first oscillation signal based on the control voltage to adjust the first frequency.

13. The method of claim 12, wherein the feedback signal is a first feedback signal, the error is a first error, the control voltage is a first control voltage, the voltage controlled oscillator is a first voltage controlled oscillator, and generating, by the second PLL circuit, the second oscillation signal having the second frequency with phase locked to the first oscillation signal comprises:
frequency-dividing the first oscillation signal;
frequency-dividing the second oscillation signal to generate a second feedback signal;
detecting a second error between the second feedback signal and the frequency-divided first oscillation signal;
generating a second control voltage based on the second error; and
controlling a second voltage controlled oscillator that generates the second oscillation signal based on the second control voltage to adjust the second frequency.

14. The method of claim 13, further comprising:
frequency-dividing the second oscillation signal.

15. The method of claim 13, further comprising:
adjusting the frequency-divisions for the first oscillation signal and the second oscillation signal to adjust the second frequency.

16. An integrated circuit (IC) chip, comprising a first phase locked loop (PLL) circuit configured to generate a first oscillation signal having a first frequency based on a reference signal having a reference frequency;
a second PLL circuit configured to receive the first oscillation signal and generate a second oscillation signal having a second frequency based on the first oscillation signal; and
a power amplifier configured to operate based on a periodic signal generated based on the second oscillation signal, a frequency difference between the first oscillation signal and the periodic signal being larger than a threshold.

17. The IC chip of claim 16, wherein the first PLL circuit is configured to have a first bandwidth that is smaller than a modulation frequency in the power amplifier and the second PLL circuit is configured to have a second bandwidth that is larger than the modulation frequency in the power amplifier.

18. The IC chip of claim 16, wherein the first PLL circuit comprises:
a divider configured to frequency-divide the first oscillation signal to generate a feedback signal;
an error detecting and controlling circuit configured to detect an error between the feedback signal and the reference signal and generate a control voltage based on the error; and
a voltage controlled oscillator configured to adjust the first frequency based on the control voltage.

19. The IC chip of claim 18, wherein the divider is a first divider, the feedback signal is a first feedback signal, the error detecting and controlling circuit is a first error detecting and controlling circuit, the error is a first error, the control voltage is a first control voltage, the voltage controlled oscillator is a first voltage controlled oscillator, and the second PLL circuit comprises:
a second divider configured to frequency-divide the first oscillation signal;
a third divider configured to frequency-divide the second oscillation signal to generate a second feedback signal;
a second error detecting and controlling circuit configured to detect a second error between the second feedback signal and the frequency-divided first oscillation signal and generate a second control voltage based on the second error; and
a second voltage controlled oscillator configured to adjust the second frequency based on the second control voltage.

20. The IC chip of claim 19, further comprising:
a fourth divider configured to frequency-divide the second oscillation signal to generate the periodic signal.

21. The IC chip of claim 19, further comprising:
a controller configured to control at least one of the first divider, the second divider and the third divider to adjust the second frequency in a range.
